(19) United States
(12) Patent Application Publication
(10) Pub. No.: US 2005/0180110 A1
(43) Pub. Date: Aug. 18, 2005

(54) Heat dissipation structure

(76) Inventors: Lin I-Yung, Taipei (TW); Huang Meng-Cheng, Taipei (TW)

Correspondence Address: Yi-Wen Tseng, 4331 Stevens Battle Lane, Fairfax, VA, 22033, US

(21) Appl. No.: 10/779,700

(22) Filed: Feb. 18, 2004

(51) Int. Cl. H05K 7/20

(52) U.S. Cl. 361/700

(57) ABSTRACT

A heat dissipation structure includes a heat sink installed over a heat generating electronic device and a plurality of heat pipes. Proximal ends of the heat pipes are located on the heat sink, and distal ends of the heat pipes extend outside of the heat sink and are connected to a set of fins. The structure is characterized in a plurality of conductor blocks formed on the heat sink at two sides of each heat pipe to aid heat absorption of the heat pipe. Therefore, the lifetime of the heat pipes are prolonged, and the heat dissipation performance is enhanced.

### BACKGROUND OF THE INVENTION

The present invention relates to heat dissipation structure, and more particular, to a heat dissipation device used for dissipating heat generated by an electronic device.

The conventional heat dissipation device 10a used in a central processing unit (CPU) 51a of a printed circuit board 5a is illustrated in FIG. 1. The heat dissipation device 10a includes a heat sink 1a installed on the CPU 51a and a plurality of heat pipes 2a. The material for fabricating the heat sink 1a includes aluminum. The heat pipes 2a include wick structures and working fluids filled therein, such that thermal energy is absorbed and discharged by the flow and phase transition of the working fluids. As shown, one ends of the heat pipes 2a are located on the heat sink 1a, and the other ends of the heat pipes 2a extend outside of the heat sink 1a. A set 3a of fins 31a is installed along one side of the heat pipes 2a. A fan (not shown) may be installed at one side of the fins 31a. In application, heat generated by the CPU 51a is conducted inside of the heat pipes 2a via the heat sink 1a. The working fluid in the heat pipes 2a absorbs and delivers the heat to the other ends of the heat pipes 2a extending outside of the heat sink 1a. The heat at the other ends of the heat pipes 2a is then conducted to the set of fins 3a and dissipated thereby.

When the operation speed of the CPU 51a is greatly increased, the heat generated thereby is much higher. If all the heat generated by the CPU 51a is absorbed by the heat pipes 2a, the conduction efficiency of the heat pipes will be degraded. The high temperature caused by excessive thermal energy may even cause phase transition of the working fluid in the heat pipes 2a to shorten the lifetime thereof.

### BRIEF SUMMARY OF THE INVENTION

The present invention provides a heat dissipation structure with enhanced heat dissipation performance.

The present invention further provides a heat dissipation structure of which the operation power of the heat pipes is mitigated, such that the lifetime of the heat pipes is prolonged.

The heat dissipation structure provided by the present invention includes a heat sink installed on a heat generating electronic device and a plurality of heat pipes. Proximal ends of the heat pipes are located on the heat sink, while distal ends of the heat pipes extend outside of the heat sink and are connected to a set of fins 3. The heat dissipation device further comprises a plurality of thermal conductor blocks formed on the heat sink at two sides of the heat pipes, such that a portion of the heat generated by the electronic device is absorbed by the thermal conductor blocks to mitigate the operation power of the heat pipes.

The present invention is characterized in the thermal conductor blocks fabricated from material such as copper, aluminum or alloy of copper and aluminum. Therefore, the thermal conductor blocks have heat storage function to aid in heat absorption of the heat pipes. Further, the thermal conductor blocks can be used as reinforcing ribs of the heat dissipation structure.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

These, as well as other features of the present invention, will become apparent upon reference to the drawings wherein:

FIG. 1 shows a conventional heat dissipation structure;

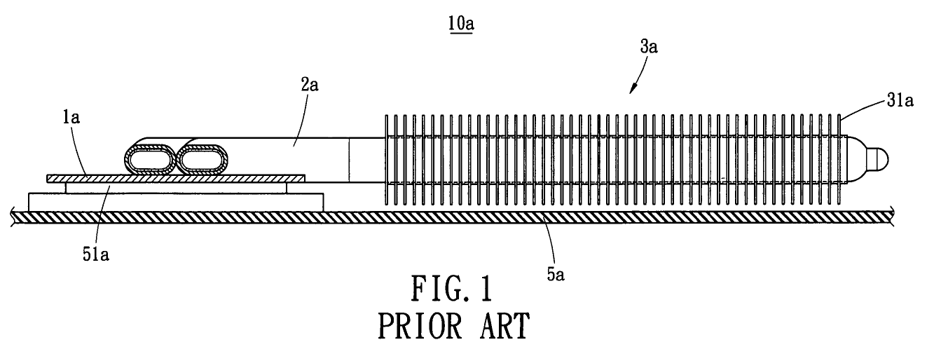

FIG. 2 shows an exploded view of a heat dissipation structure provided by the present invention;

FIG. 3 shows a perspective view of the heat dissipation structure as shown in FIG. 2;

FIG. 4 shows a side view of the heat dissipation structure;

FIG. 5 shows a cross sectional view of the heat dissipation structure;

FIG. 6 shows a cross sectional view of a heat dissipation structure in another embodiment;

FIG. 7 shows a perspective view of a heat dissipation structure in another embodiment; and

FIG. 8 shows a perspective view of a heat dissipation structure in yet another embodiment.

### DETAILED DESCRIPTION OF THE INVENTION

Reference will now be made in detail to the preferred embodiments of the present invention, examples of which are illustrated in the accompanying drawings. Wherever possible, the same reference numbers are used in the drawings and the description to refer to the same or like parts.

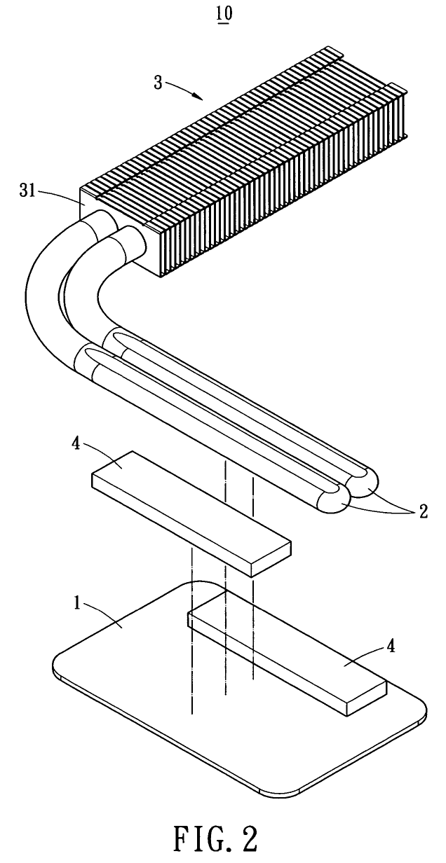

The present invention provides a heat dissipation structure. As shown in FIG. 2, the heat dissipation structure 10 includes a heat sink 1 attached on a central processing unit (CPU) 51. The heat sink 1 preferably fabricated from aluminum or copper, for example.

The heat dissipation structure 10 includes a plurality of heat pipes 2. In this embodiment, the heat pipes 2 are in L shape and include wick structures and working fluids filled therein. One ends of the heat pipes 2 are located on the heat sink 1, while the other ends of the heat pipes 2 extend outside of the heat sink 1 and are connected to a set of fins 3. The set of fins 3 includes a plurality of fins 31 equally spaced from each other. A fan can be installed on top of or at one side of the set of fins 3.

As shown in FIG. 2, a plurality of thermal conductor blocks 4 are formed on the heat sink 1 at two sides of the heat pipes 2. The material for fabricating the thermal conductor blocks 4 includes copper, aluminum or alloy of copper and aluminum. In this embodiment, copper is used to fabricate the thermal conductor blocks 4 to aid in heat storage and absorption. In addition, the thermal conductor blocks 4 serve as the reinforcing ribs of the heat dissipation structure 10.

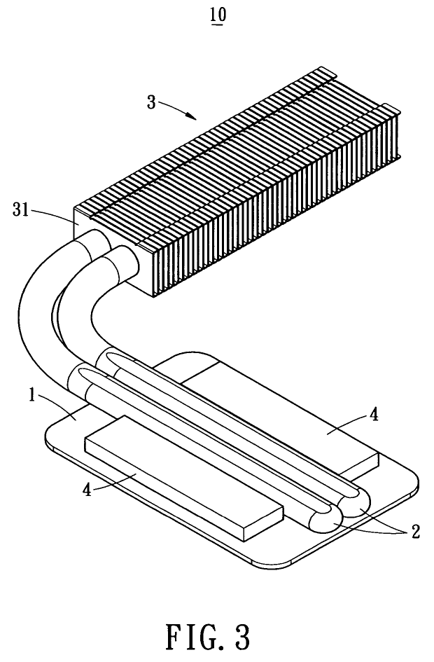

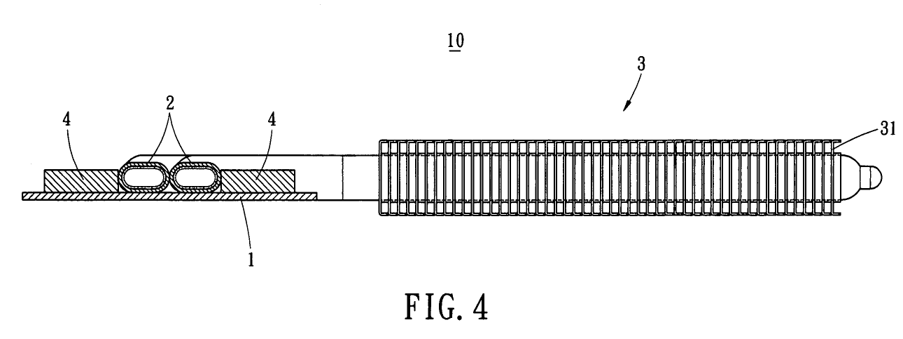

In assembly process, referring to FIGS. 3 and 4, the proximal ends of the heat pipes 2 are installed on the heat sink 1, and two thermal conductor blocks 4 are installed on the heat sink 1 at two sides of the heat pipes 2. The distal ends of the heat pipes 2 are then connected to the set of fins 3.

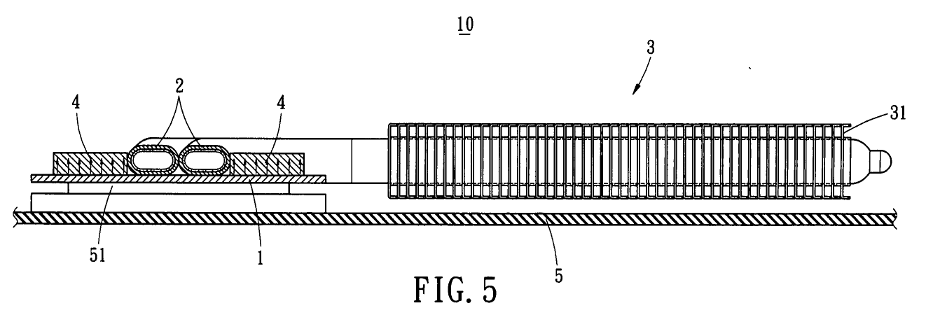

As shown in FIG. 5, in application, the heat sink 1 is installed on the CPU 51 of the printed circuit board 5. When the CPU 51 is operating, a portion of the heat generated thereby is conducted into the heat pipes 2 via the heat sink 1. The wick structures and working fluids inside the heat pipes 2 then deliver the heat to the set of fins 3. The other portion of the heat generated by the CPU 51 is absorbed by the thermal conductor blocks 4 and stored thereby as a buffer of the heat pipes 2. When the portion absorbed by the heat pipes 2 is delivered to the set of fins 3, the heat stored in the thermal conductor blocks 4 is absorbed by the heat pipes 2. The other portion of the heat is then delivered to and dissipated by the set of fins 3.

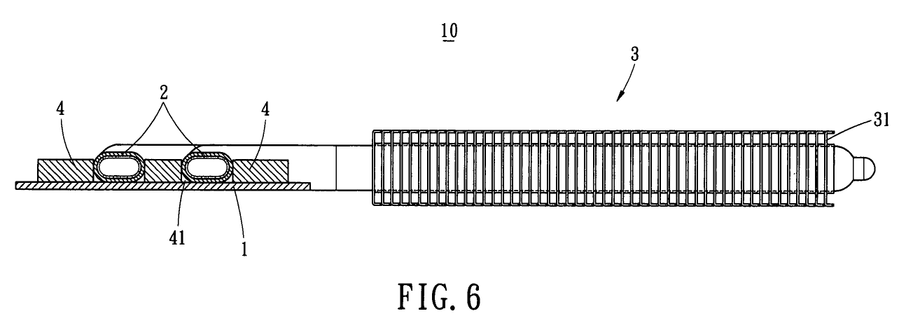

FIG. 6 shows another embodiment of the present invention. As shown, recessed channels 4 are formed in the thermal conductor blocks 4, such that the heat pipes 2 can be installed in the recessed channels 4 of the thermal conductor blocks 4. Similarly, a portion of the heat generated by the CPU 51 is absorbed by the heat pipes 2 directly, and a portion of the heat is buffered by the thermal conductor blocks 4.

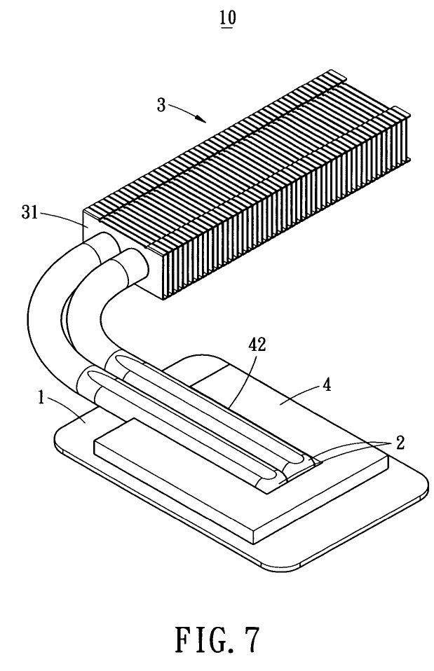

FIG. 7 shows another embodiment of the heat dissipation structure 10, in which a large thermal conductor block 4 is grooved with a non-through slot 42. The thermal conductor block 4 is thus configured with a U-shape plate. The heat pipes 2 are then embedded in the thermal conductor block 4 at the slot 42.

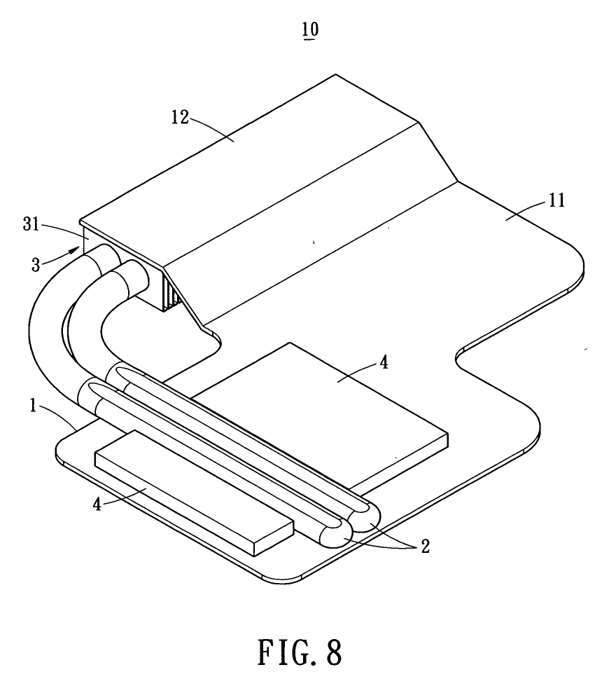

Referring to FIG. 8, the heat sink 1 may expand with an extension 11 covering the set of fins 3. The portion of the extension 11 covering the set of fins 3 is referred as the guide portion and denoted by the reference numeral 12 as shown in FIG. 8. Thereby, the heat absorbed by the thermal conductor blocks 4 can be guided to the set of fins 3 via the guide part 12 and the extension 11. Or the heat delivered to the set of fins 3 can be guided to the extension 11 via the guide part 12 to avoid heat accumulation.

Accordingly, the heat storage function of the thermal conductor blocks 4 absorbs a portion of heat generated by the electronic device, so as to buffer the operation power of the heat pipes 2. Therefore, the lifetime of the heat pipes 2 is prolonged, and the heat dissipation performance of the heat dissipation device 10 is improved. Further, the heat dissipation structure 10 is stronger since the thermal conductor blocks 4 can be used as reinforcing ribs.

This disclosure provides exemplary embodiments of the present invention. The scope of this disclosure is not limited by these exemplary embodiments. Numerous variations, whether explicitly provided for by the specification or implied by the specification, such as variations in shape, structure, dimension, type of material or manufacturing process may be implemented by one of skill in the art in view of this disclosure.

1. A heat dissipation structure, comprising:
a heat sink, installed on a heat generating electronic device;
at least one heat pipe, having a proximal end located on the heat sink and a distal end extends outside of the heat sink, wherein the heat pipe includes a wick structure and a working fluid therein;
a set of fins connected to the distal end of the heat pipe;
at least one thermal conductor block installed on the heat sink and adjacent to the heat pipe, the thermal conductor block is operative to store thermal energy.

2. The structure of claim 1, wherein the heat sink further comprises an extension extends towards the set of fins.

3. The structure of claim 1, wherein the extension extends over the set of fins to form a guide portion.

4. The structure of claim 1, wherein the electronic device includes a central processing unit.

5. The structure of claim 1, comprising two thermal conductor blocks at two sides of the heat pipe.

6. The structure of claim 1, wherein the thermal conductor includes a recessed channel for accommodating the heat pipe therein.

7. The structure of claim 1, wherein the thermal conductor block includes a U-shape plate on which a non-through slot is formed for embedding the heat pipe therein.

8. The structure of claim 1, wherein the thermal conductor block is fabricated from copper.

9. The structure of claim 1, wherein the thermal conductor block is fabricated from aluminum.

10. The structure of claim 1, wherein the thermal conductor block is fabricated from alloy of copper and aluminum.

11. The structure of claim 1, wherein the thermal conductor block is fabricated in a form of reinforcing rib.
